(19) United States
(12) Patent Application Publication
(10) Pub. No.: US 2017/0005251 A1
(43) Pub. Date: Jan. 5, 2017

(54) THERMOELECTRIC DEVICE

(71) Applicant: INTERNATIONAL BUSINESS MACHINES CORPORATION, Armonk, NY (US)

(72) Inventors: Heike E. Riel, Baech (CH); Volker Schmidt, Zuerich (CH)

(73) Assignee: INTERNATIONAL BUSINESS MACHINES CORPORATION, Armonk, NY (US)

(21) Appl. No.: 15/104,565

(22) PCT Filed: Dec. 8, 2014
(86) PCT No.: PCT/IB2014/066696

§ 371 Date: Jun. 15, 2016

(30) Foreign Application Priority Data
Dec. 17, 2013 (GB) 1322246.8

(51) Int. Cl. H01L 35/32; H01L 35/34; H01L 35/10

(52) U.S. Cl. CPC H01L 35/32; H01L 35/10; H01L 35/34

(57) ABSTRACT

A thermoelectric device for transferring heat from a heat source to a heat sink. The device includes a first thermoelectric leg pair having a first leg including an n-type semiconductor material and a second leg including a p-type semiconductor material, wherein the first leg and the second leg are electrically coupled in series; a second thermoelectric leg pair has a third leg including an n-type semiconductor material and a fourth leg including a p-type semiconductor material, wherein the third leg and the fourth leg are electrically coupled in series; a first contact placed between the first leg and the fourth leg and a second contact placed between the second leg and the third leg. A method for manufacturing a thermoelectric device is also provided.

### CROSS-REFERENCE TO RELATED APPLICATION

This application claims priority under 35 U.S.C. §371 from PCT Application PCT/IB2014/066696, filed on Dec. 8, 2014, which claims priority from United Kingdom Patent Application No. 1322246.8 filed Dec. 17, 2013. The entire contents of both applications are incorporated herein by reference.

### FIELD OF INVENTION

This disclosure generally relates to heat transfer devices, in particular to thermoelectric devices and modules for transferring heat from a heat source to a heat sink. More particularly, this disclosure relates to thermoelectric devices that can be coupled to objects to be heated or cooled. Further, methods for manufacturing a thermoelectric device and module are described.

### BACKGROUND

Thermoelectric devices for cooling are used to transfer excess heat from electronic devices, such as sensors, active electro-optical components, infrared CCD chips and the like. As many electronic devices have low power dissipation, additional cooling means are desired. Electric cooling was first discovered by John Charles Peltier who observed that a current flowing through a junction between dissimilar conductors, such as n- or p-type semiconductors, can induce heat or cooling as a function of the current flow through the junction. This effect is called the Peltier- or thermoelectric effect. The temperature can be increased or lowered depending on the current direction through the junction.

Thermoelectric devices are often used as heat pumps placed between a heat source and a heat sink wherein the heat source can be an electric component and the heat sink sometimes is a surface plate or a convection heat sink. Conventional thermoelectric cooling devices often use multiple stages to stepwise cool down an object or transfer heat from a heat source away. Such multi-stage modules essentially consist of separate thermoelectric modules stacked on top of each other. This leads to additional space requirements and an increase in expenditure due to the plurality and complexity of thermoelectric components involved. It is generally desirable to increase the efficiency of thermoelectric cooling modules.

### SUMMARY OF THE INVENTION

According to an embodiment of a first aspect of the invention, there is provided a thermoelectric device for transferring heat from a heat source to a heat sink includes a first thermoelectric leg pair having a first leg including an n-type semiconductor material and a second leg including a p-type semiconductor material. The first leg and the second leg are electrically coupled in series. Further, a second thermoelectric leg pair having a third leg including an n-type semiconductor material and a fourth leg including ptype semiconductor material is included. The first leg and the second leg of the second thermoelectric leg pair (third leg and fourth leg) are electrically coupled in series. A first contact is placed between the first leg and the fourth leg, and a second contact is placed between the second leg and the third leg.

According to another aspect, there is a method for manufacturing a thermoelectric device for transferring heat from a heat source to a heat sink including: providing a first thermoelectric leg pair having a first leg including an n-type semiconductor material and a second leg including a p-type semiconductor material; electrically coupling the first leg and the second leg of the first thermoelectric leg pair in series; providing a second thermoelectric leg pair having a third leg including an n-type semiconductor material and a fourth leg including a p-type semiconductor material; electrically coupling the third leg and the fourth leg of the second thermoelectric leg pair in series; placing a first contact between the first leg and the fourth leg; and placing a second contact between the second leg and the third leg.

### BRIEF DESCRIPTION OF SEVERAL VIEWS OF THE DRAWINGS

In the following, embodiments of thermoelectric devices and methods and devices relating to the manufacture of thermoelectric devices are described with reference to the enclosed drawings.

FIG. 1 shows a schematic diagram of a first embodiment of a thermoelectric device.

FIG. 2 shows a diagram illustrating temperature distributions in embodiments of thermoelectric devices.

FIG. 3 shows a schematic diagram of an embodiment of a thermoelectric module.

FIG. 4 is a flow chart showing method steps involved in a method for manufacturing a thermoelectric device.

FIGS. 5 and 6 illustrate method steps involved in manufacturing a embodiment of a thermoelectric device.

Like or functionally like elements in the drawings have been allotted the same reference characters, if not otherwise indicated.

### DETAILED DESCRIPTION OF THE INVENTION

It is therefore an aspect of the present disclosure to provide an improved thermoelectric device for transferring heat from a heat source to a heat sink. A thermoelectric device can be in particular suitable for implementing further thermoelectric modules or arrangements.

According to an embodiment of a first aspect of the invention, there is provided a thermoelectric device for transferring heat from a heat source to a heat sink includes a first thermoelectric leg pair having a first leg including an n-type semiconductor material and a second leg including a p-type semiconductor material. The first leg and the second leg are electrically coupled in series. Further, a second thermoelectric leg pair having a third leg including an n-type semiconductor material and a fourth leg including ptype semiconductor material is included. The first leg and the second leg of the second thermoelectric leg pair (third leg and fourth leg) are electrically coupled in series. A first contact is placed between the first leg and the fourth leg, and a second contact is placed between the second leg and the third leg.

According to an embodiment of a second aspect a method for manufacturing a thermoelectric device or module includes the steps of: providing a first thermoelectric leg pair having a first leg including an n-type semiconductor material and a second leg including a p-type semiconductor material; electrically coupling the first leg and the second leg of the first thermoelectric leg pair in series; providing a second thermoelectric leg pair having a third leg including an n-type semiconductor material and a fourth leg including a p-type semiconductor material; electrically coupling the first leg and the second leg of the second thermoelectric leg pair (third and fourth leg) in series; placing a first contact between the first leg and the fourth leg; and placing a second contact between the second leg and the third leg.

According to an embodiment, two legs forming a pair can be arranged next to each other, e.g. in parallel to each other, and placed between interfaces to a heat source and a heat sink, respectively. In operation of thermoelectric devices according to embodiments of the invention, an electric current can be injected through the second and the first leg as well as through the third and the fourth leg, wherein at the junction between the p- and n-type semiconductor material the Peltier effect can be employed. As a result, there is a temperature gradient between the side of the leg pair facing to the heat source and the side of the leg pair facing to the heat sink. For example, the heat source can be an electronic device that needs to be cooled. The heat sink can be a dissipator, for example.

The first thermoelectric leg pair and the second thermoelectric leg pair can include four sections including p- and n-type thermoelectric material. The sections can be separated by a highly conducting material such as metal films. Electrical current can be inserted through the first and/or the second contact such that a temperature gradient occurs. Via the positioning of the first and/or the second contact, a current distribution in the legs can be adjusted, thereby generating a specific and desired temperature distribution over the thermoelectric device. For example, the first and the second thermoelectric leg pair can be thermally coupled in series between the heat source and the heat sink. Further, the first leg and the second leg can be thermally coupled in parallel between the heat source and the heat sink, and the third leg and the fourth leg can be thermally coupled in parallel between the heat source and the heat sink. Further, the first and the second thermoelectric leg pair can be electrically coupled in parallel.

Embodiments of the thermoelectric device including at least four legs with the specified conduction types and contacts can form an efficient thermoelectric device. By adjusting the position of the first and second contacts, a desirable temperature distribution over the thermoelectric device can be obtained.

In embodiments of the thermoelectric device, the first contact and the second contact are adapted to apply a voltage to the first and second thermoelectric leg pair. The voltage can generate a current through the respective leg pairs thereby creating a specific temperature distribution due to the thermoelectric effects.

In embodiments, the first and the second contact can be arranged between the first leg and the fourth leg and/or between the second leg and the third leg such that, in particular, in operation a Joule heating of the legs is concentrated towards the side of the heat sink.

It can be an advantage that the regions of the thermoelectric device that are close to the heat sink are heated by a current to a higher extend than the regions that are close to the heat source. It can be desirable to create a temperature profile across the thermoelectric device from the heat source to the heat sink where the increase in temperature is steeper in distal regions from the heat source.

In embodiments of the thermoelectric device, the first thermoelectric leg pair has a higher electric resistance than the second thermoelectric leg pair. By tuning the resistance of the legs, a specific current distribution can be obtained, thereby adjusting a temperature profile across the device.

In embodiments, the first and second contacts are sandwiched metal layers between the semiconductor materials of the legs. The contacts are preferably highly heat-conducting and can include, for example, materials like copper, aluminum, silver, nickel, brass, stainless steel, aluminum or the like.

In embodiments, the first thermoelectric leg pair has a first length, and the second thermoelectric leg pair has a second length which is unequal to the first length.

One can assume that the lengths of the legs forming respective thermoelectric leg pair have same or at least similar length. Due to slight imperfections the actual length of the first/third leg can differ from the length of the second/fourth leg. The length of the leg pair however is essentially the length of a leg included in the pair. A reasonable tolerance is assumed.

In embodiments, the first length is in particular larger/greater than the second length. When the first length of the legs or leg pair attached to the heat source is large in comparison to the second length of the legs or leg pair attached to the heat sink, most of the electric current runs through the second leg pair. This can result in a further increase of the temperature due to Joule heating. According to an embodiment the first length is at least three times larger than the second length. In further embodiments, the first length is at least ten times larger than the second length, and even more preferable, the first length is 100 times larger than the second length.

Extremely short thermoelectric leg pairs facing towards the heat sink can be manufactured by deposition techniques, for example. In embodiments of a method for manufacturing a thermoelectric device, the second thermoelectric leg pairs are, for example, deposited as a thin film on a substrate or on a metal layer forming the contacts.

An embodiment of a thermoelectric module includes at least a first and a second thermoelectric device as described above. Then, the first contact of the first thermoelectric device is coupled to the second contact of the second thermoelectric device.

For example, current can be injected into the first contact of the first thermoelectric device and exits the module at the second contact or at the second thermoelectric device. One can contemplate a thermoelectric module including more than two thermoelectric devices which are electrically connected in series. For example, a thermoelectric module can include a plurality of thermoelectric devices electrically coupled in series such that an electrical current can flow through a sequence of alternatingly arranged n-type and p-type legs. The current preferably flows partially through the legs of the first thermoelectric pairs and partially through the legs of the second thermoelectric pairs.

Embodiments of the thermoelectric module can reach efficiencies that are higher than conventional multi-stage thermoelectric modules. This is because—due to the arrangement of n- and p-type legs across the thermoelectric module from the heat source to the heat sink—an advantageous distribution of Joule heating and Peltier cooling can be obtained, thereby increasing the efficiency of the module.

One can further contemplate attaching several thermoelectric modules as a stack to achieve an even better heat transfer.

Certain embodiments of the presented thermoelectric device and the method for fabricating a thermoelectric device can include individual or combined features, method steps or aspects as mentioned above or below with respect to exemplary embodiments.

In this disclosure, the term “heat source” refers to an element or object from which excess heat is to be transferred, e.g. through a thermoelectric device. The term “heat sink” refers to an element or object that can dissipate or capture heat. Generally, the heat source is cooled down by the thermoelectric device, and the heat sink is heated up. The thermoelectric device as disclosed can be considered a heat pump for transferring heat from the heat source to the heat sink. A “leg” is a structure having a longitudinal extension and a lateral extension. A leg can have a rod-like or column-like geometry. In some cases the longitudinal extension exceeds the lateral extension. However, other aspect ratios can be contemplated. In embodiments of the legs the longitudinal extension is in the direction from the heat source to the heat sink or vice versa. A leg can be assumed to carry an electric current and a thermal current essentially in parallel. The term “junction” refers to an interface between two materials that have different electric properties. E.g. a metal-semiconductor interface can be called a junction. Similarly, a sequence of p-n-materials can be considered a junction.

The thermoelectric device employs the Peltier effect or thermoelectric effect. P- and n-type doped semiconductor materials can be used as thermoelectric materials. For example, bismuth, antimony, bismuth telluride, bismuth selenide, bismuth antimonide, antimon telluride, lead telluride, lead selenide, lead antimonide, iron silicide, manganese silicide, cobalt silicide, magnesium silicide, chromium silicide, calcium manganese oxide or combinations thereof can be employed. One can contemplate other semiconductor materials that show a thermoelectric effect.

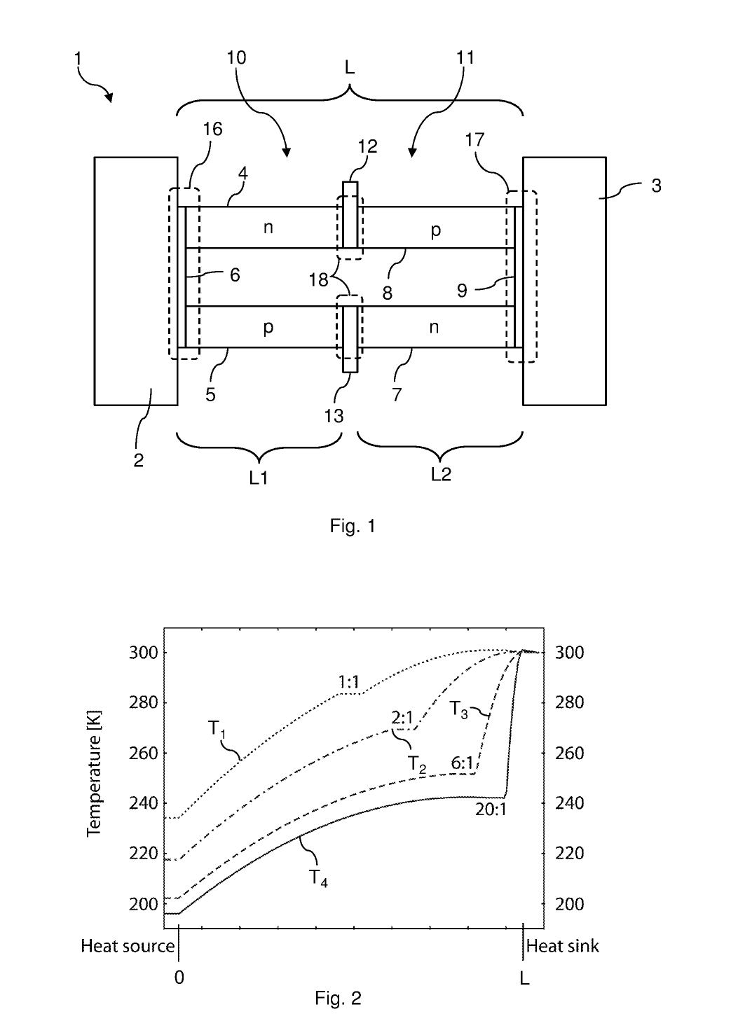

FIG. 1 shows a first embodiment of a thermoelectric device 1. The thermoelectric device 1 is, for example, used for cooling an electric device that dissipates heat. In FIG. 1, a heat source 2 and a heat sink 3 are shown. The heat source can be an electric component or another device that is supposed to be cooled. The heat sink 3 can be, for example, a dissipator or other cooling element.

There are two thermoelectric leg pairs 10 and 11 that are arranged thermally in series between the heat sink 3 and the heat source 2. Each thermoelectric leg pair 10, 11 includes a first and a second leg 4, 5, 7, 8 having specific properties. The first thermoelectric leg pair 10 includes a first leg 4 including an n-type semiconductor material and a second leg 5 including a p-type semiconductor material. At the ends facing towards the heat source 2, a metal layer 6 couples the two legs 4, 5 electrically. Similarly, the second thermoelectric leg pair 11 has a first leg 7 including an n-type semiconductor material and a second leg 8 including a p-type semiconductor material. The two legs 7, 8 of the second thermoelectric leg pair 11 are electrically coupled through a metal layer 9 at their ends facing towards the heat sink 3.

There are electric contacts 12, 13 with contact 12 provided between the first n-type leg 4 of the first thermoelectric leg pair 10 and the second p-type leg 8 of the second thermoelectric leg pair 11 and contact 13 provided between the second p-type leg 5 of the first thermoelectric leg pair 10 and the first n-type leg 7 of the second thermoelectric leg pair 11.

The first leg 7 of the second thermoelectric leg pair 11 including a n-type semiconductor material can be denoted as third leg. The second leg 8 of the second thermoelectric leg pair 11 including a p-type semiconductor material can be denoted as fourth leg.

The two contacts 12, 13 are adapted such that an electric current can be inserted into the legs such that a partial current flows through the first leg pair 10, and a partial current flows through the second leg pair 11. In particular, at the junctions indicated as dashed boxes 16, 17, 18, due to the Peltier or thermoelectric effect heat or cooling is effected, respectively. At the interfaces or junctions 18 the Peltier effect can occur due to the current flow from the central metal contact 12, 13 into the p- or n-type material, i.e. from contact 12 into legs 4 and 8, and from contact 13 into legs 5 and 7. If these two currents (from 12 into 4 and 12 into 8) are similar and thermoelectrically similar materials are used at the contacts 12, 13 the cooling on one side of 12/13 is roughly compensated by heating on the other side.

The entire embodiment of a thermoelectric device 1 has a length L between the two metal layers 6, 9. One can neglect the thickness of the metal layers 6, 9. The first and the second leg 4, 5 have a length L1, and the third and fourth leg 7, 8 have a length L2. L1 denotes the length of the thermoelectric leg pair 10 that is next to the heat source 2 (first thermoelectric leg pair), and L2 denotes the length of the second thermoelectric leg pair 11 attached or close to the heat sink 3.

Investigations of the applicant show that if current is injected via the contacts 12, 13 between the two thermoelectric leg pairs 10, 11, i.e. a voltage V is applied between the contacts 12, 13, the efficiency of the thermoelectric device increases if L1 is greater/larger than L2.

For example, assuming an n- and p-type thermoelectric material having an electrical conductivity of 1·10⁵ 1/(Ω·m), a thermal conductivity of 3 W/(mK) and a Seebeck coefficient of 3·10 ⁻⁴ V/K for the p-type material and −3·10 ⁻⁴ V/K for the n-type material, temperature curves along the profile of the thermoelectric device as shown in FIG. 2 are obtained. FIG. 2 shows a temperature profile across the thermoelectric device 1 according to FIG. 1 when at T=300 K a ZT value of 0.9 is assumed and a voltage is applied between the first and the second contact 13, 12. The contacts 6, 9, 12, 13are assumed to have a electrical conductivity of 6·10⁷ 1/(Ω·m).

The ZT value is a figure denoting the ability of a given material to efficiently produce thermoelectric power and is defined by:

$$ZT = \frac{σ {S}^{2} T}{λ}$$

It depends on the Seebeck coefficient S, the thermal conductivity λ, the electrical conductivity σ, and the temperature T.

The dotted curve T₁ shows the temperature along the length of the device in a configuration, where L1=L2 or L1/L2=1 and a voltage drop of V=0.09 V is applied. A temperature difference of roughly 66 K can be obtained between a heat sink 3 and a heat source 2. The dash-dotted curve T₂ refers to a configuration where the ratio between L1 and L2 is L1/L2=2. Assuming a voltage drop of 0.11 V, a temperature spread between the left-hand side and the right-hand side of roughly 83 K can occur. The dotted curve T₃ refers to a configuration where the ratio between L1 and L2 is L1/L2=6. Assuming a voltage drop of 0.13 V, a temperature spread between the left-hand side and the right-hand side of roughly 98 K can occur. Assuming an even higher ratio between L1 and L2, the temperature spread can still be increased. Curve T₄ shows the temperature profile across the thermoelectric device 1, when L1=20·L2 and a voltage of V=0.14 is applied to the contacts 12, 13. The temperature difference is then roughly 104 K.

This is mostly because the resistance of the leg pair having length L2 decreases with respect to the leg pair L1. Hence, a larger portion of the current passes through the shorter legs, i.e. the leg pair 11 that is closer to the heat sink 3. As a consequence, the Joule heating created by the current flow is concentrated towards the hotter part of the module 1. Then, one can carry away the produced heat at the right-hand side legs through the heat sink 3 easier than heat created or stemming from the heat source 2. Hence, the performance of the thermoelectric device improves.

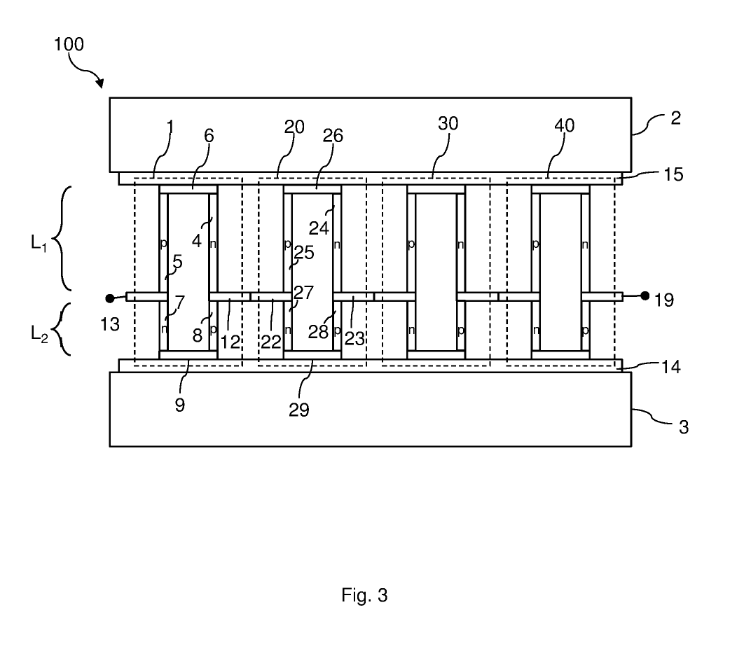

FIG. 3 shows an embodiment of a thermoelectric module. The embodiment of a thermoelectric module 100 includes several thermoelectric devices 1, 20, 30, 40 that have a similar or like configuration as shown in FIG. 1. The thermoelectric devices 1, 20, 30, 40 are placed between two substrates 14 and 15 wherein (in the orientation of FIG. 3) the lower substrate 14 is attached to the heat sink 3 and the upper substrate 15 is attached to the heat source 2. The heat source 2 can be an electric component that needs to be cooled.

The thermoelectric devices 1, 20, 30, 40 have legs 4, 5, 7, 8, 24, 25, 27, 28 including p- or n-type material as indicated in the figure. Referring to FIG. 3, the upper legs 4, 5, 24, 25, have a length L1 and the lower legs 7, 8, 27, 28 have the length L2. By tuning the ratio between L1 and L2, the efficiency of the module 100 can be adjusted.

A contact 12 between the n-type leg 4 of the first leg pair and the p-type leg 8 of the second leg pair of the first device 1 is coupled to the second contact 22 between the p-type leg 25 of the first leg pair and the n-type leg 27 of the second leg pair of the second thermoelectric device 20. The respective legs are electrically coupled in series through metal layers 6, 26 and 9, 29, respectively. A voltage is applied to the thermoelectric module 100 through contact 13 and contact 19. The contacts 13, 19 are placed and arranged such that an electric current runs through a series of alternating p- and n-type legs partially through the upper legs 5, 4, 25, 24 and partially through the lower legs 7, 8, 27, 28.

Although not expressly shown in FIG. 3 the contacts 13, 19 for applying a voltage can be placed at other location within the module. E.g. contact pads can be used that are attached to one of the substrates 14, 15. Further, embodiments can be contemplated where thermoelectric devices at the edges of the module are implemented with single thermoelectric leg pairs, e.g. metal layers 6 or 9 can be used as external contacts. Other modifications are possible.

The combined length of L1 and L2 can be, for example, between 1 and 10 mm. However, one can contemplate other sizes. A cross-section of each leg can be between 1×1 mm² and 5×5 mm² according to the embodiment. However, one can also contemplate smaller legs or larger legs or legs that are cylinder-shaped. The voltage applied across the alternatingly coupled thermoelectric legs can be between 0.1 and 10 V. However, one can also contemplate other ranges. Investigations of the applicant show that temperature differences greater than 100 K can be reached.

It is an advantage of the embodiments that no multiple stages increasing the thickness of a respective thermoelectric module are necessary. The small length or the thicknesses of the legs facing towards the heat sink 3 can be achieved, for example, by depositing a thermoelectric material on a substrate or metal pad without prefabricating the legs.

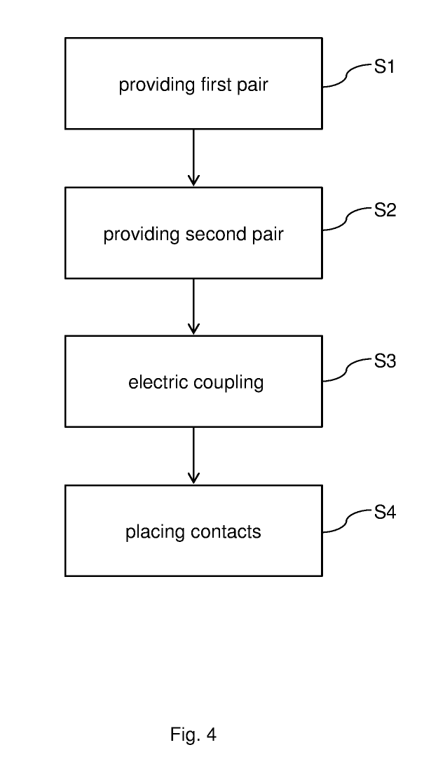

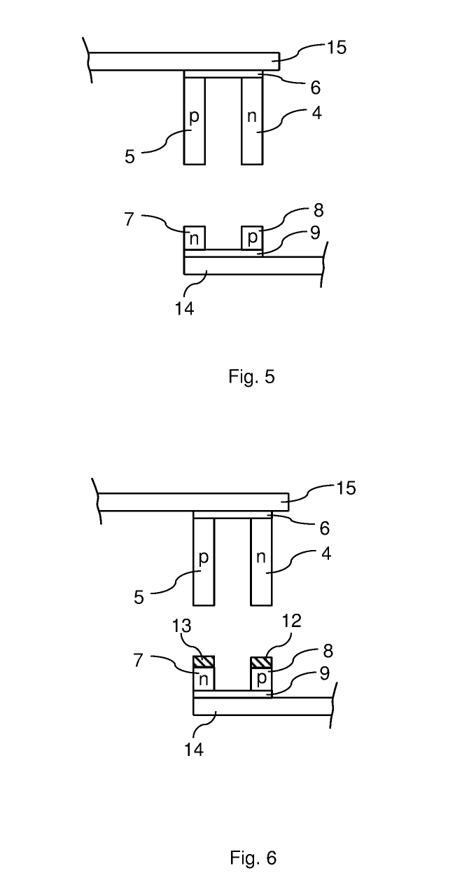

FIG. 4 shows a flowchart of an embodiment of a method for fabricating a thermoelectric device. E.g. a device according to FIG. 1 can be manufactured. FIGS. 5 and 6 illustrate some method steps. In a manufacturing method, in step S1, a first pair of thermoelectric legs is provided. This is illustrated in FIG. 5 showing a first leg 4 and a second leg 5 attached to a substrate 15 and coupled to each other through a metal layer 6 in series. The legs 4, 5 basically extend in parallel to each other along their longitudinal direction. The legs can be cut from a bulk or grown from a substrate.

Next, a second pair of thermoelectric legs is provided (step S2). FIG. 5 shows a third and a fourth leg 7, 8 placed on a second substrate 14 and coupled through a metal layer 9. In particular, the thin second thermoelectric legs can be manufactured by thin film deposition techniques. One can contemplate sputtering or electro-deposition of a thermoelectric material and patterning said material appropriately on a substrate. One can also contemplate depositing, in particular the second leg pair 7, 8, on a metal layer forming the contact 9.

The first and the second leg 4, 5 and the third and the fourth leg 7, 8 are electrically coupled through the metal layers 6, 9 in step S3.

Next, contacts are placed between the first leg 4 and the fourth leg 8, and between the second leg 5 and the third leg 7 (step S4). This is illustrated in FIG. 6. For example, the longer first and second legs 4, 5 can be cut, picked up and placed at their positions. After attaching the upper legs 4, 5 to the lower legs 7, 8 with the contacts 12, 13 in between, basically the embodiment shown in FIG. 1 is produced.

The materials chosen as the thermoelectric materials preferably have a ZT value reaching its maximum at temperatures around 230 K and 250 K. On the other hand, the thermoelectric material used for the short legs facing the heat sink preferably show a maximum ZT at higher temperatures, e.g. between 290K and 320 K.

The disclosed thermoelectric devices, modules and methods can allow for an efficient heat transfer from a heat source to a heat sink. In particular, objects that need cooling such as electric chips, CCD chips or the like can be attached to such a thermoelectric module. Embodiments of thermoelectric devices and modules according to the invention can require two substrates at most having the thermoelectric legs in between. This provides an advantage over conventional multi-stage thermoelectric modules that require several substrates to achieve the same or even lower performance.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others

1. A thermoelectric device for transferring heat from a heat source to a heat sink, the thermoelectric device comprising:
a first thermoelectric leg pair having a first leg including an n-type semiconductor material and a second leg including a p-type semiconductor material, wherein the first leg and the second leg are electrically coupled in series;
a second thermoelectric leg pair having a third leg including an n-type semiconductor material and a fourth leg IRA-including a p-type semiconductor material, wherein the third leg and the fourth leg are electrically coupled in series;
a first contact placed between the first leg the fourth leg; and
a second contact placed between the second leg and the third leg.

2. The thermoelectric device of claim 1, wherein the first and the second thermoelectric leg pair are thermally coupled in series between the heat source and the heat sink.

3. The thermoelectric device of claim 1, wherein the first leg and the second leg are thermally coupled in parallel between the heat source and the heat sink and the third leg and the fourth leg are thermally coupled in parallel between the heat source and the heat sink.

4. The thermoelectric device of claim 1, wherein the first contact and the second contact are adapted to apply a voltage to the first and second thermoelectric leg pair.

5. The thermoelectric device of claim 1, wherein the first and/or second contact are arranged between the first leg and the fourth leg and/or between the second leg and the third leg such that a Joule heating of the legs is concentrated towards the side of the heat sink.

6. The thermoelectric device of any one of claim 1, wherein the first thermoelectric leg pair has a higher electric resistance than the second thermoelectric leg pair.

7. The thermoelectric device of claim 1, wherein the first and/or second contact are sandwiched metal layers between the material of the legd.

8. The thermoelectric device of claim 1, wherein the first thermoelectric leg pair has a first length, and the second thermoelectric leg pair has a second length unequal to the first length.

9. The thermoelectric device of claim 8, wherein the first length is larger than the second length.

10. The thermoelectric device of claim 8, wherein the first length is at least three times larger than the second length.

11. A thermoelectric module comprising:
at least a first and a second thermoelectric device of claim 1, wherein the first contact of the first thermoelectric device is coupled to the second contact of the second thermoelectric device.

12. The thermoelectric module of claim 11, further comprising:
a plurality of thermoelectric devices electrically coupled in series such that an electrical current may flow through a sequence of alternatingly arranged n-type and p-type legs.

13. The thermoelectric module of claim 8, wherein the plurality of thermoelectric devices forms an array arranged on a substrate.

14. A method for manufacturing a thermoelectric device for transferring heat from a heat source to a heat sink, the method comprising:
providing a first thermoelectric leg pair having a first leg including an n-type semiconductor material and a second leg including a p-type semiconductor material;
electrically coupling the first leg and the second leg of the first thermoelectric leg pair in series;
providing a second thermoelectric leg pair having a third leg including an n-type semiconductor material and a fourth leg including a p-type semiconductor material;
electrically coupling the third leg and the fourth leg of the second thermoelectric leg pair in series;
placing a first contact between the first leg and the fourth leg; and
placing a second contact between the second leg and the third leg.

15. The method of claim 14, wherein providing a second thermoelectric leg pair comprises:
depositing an n-type semiconductor material on a metal layer forming a contact for forming the third leg and;
depositing a p-type semiconductor material on a metal layer forming a contact for forming the fourth leg.
